(19) United States
(12) Patent Application Publication
(10) Pub. No.: US 2025/0355038 A1
(43) Pub. Date: Nov. 20, 2025

(54) INTEGRATED CIRCUIT

(71) Applicant: FUJI ELECTRIC CO., LTD., Kawasaki-shi (JP)

(72) Inventor: Daisuke ISOBE, Matsumoto-city (JP)

(73) Assignee: FUJI ELECTRIC CO., LTD., Kawasaki-shi (JP)

(21) Appl. No.: 19/090,035

(22) Filed: Mar. 25, 2025

(30) Foreign Application Priority Data
May 15, 2024 (JP) 2024-079215
Jul. 17, 2024 (JP) 2024-114349

(51) Int. Cl. G01R 31/27; G01R 31/26; H02H 9/02

(52) U.S. Cl. CPC G01R 31/275; G01R 31/2639; H02H 9/025

(57) ABSTRACT

An integrated circuit, including: a first transistor and a second transistor, each having an electrode on a high potential side thereof to receive a redetermined voltage, a control electrode to receive a control voltage, and an electrode on a low potential side thereof, the first transistor sending a first current to a load connected to the integrated circuit, and the second transistor sending a second current corresponding to the first current; a third transistor connected between the electrode on the low potential side of the second transistor and a predetermined line; an operational amplifier controlling the third transistor such that voltages at the electrodes on the low potential sides of the first transistor and the second transistor are equal; and a subtractor circuit that, in response to a first condition being satisfied, sends a third current to a ground, the third current being a part of the second current.

### CROSS-REFERENCE TO RELATED APPLICATIONS

The present application claims priority pursuant to 35 U.S.C. § 119 from Japanese patent application numbers Nos. 2024-079215 and 2024-114349, filed May 15, 2024, and Jul. 17, 2024, respectively, of which full contents are incorporated herein by reference.

### BACKGROUND

### Technical Field

The present disclosure relates to an integrated circuit.

### Description of the Related Art

As a method of detecting a load current of a transistor that drives a load, known is a method of detecting the current of a so-called sense transistor that passes a current corresponding to the load current (for example, Japanese patent application publication No. 2017-037493).

In general, the size ratio between a sense transistor and a transistor that drives a load (hereinafter, referred to as main transistor) is determined such that the current flowing through the sense transistor and the current flowing through the main transistor is a predetermined ratio.

However, if the size ratio between the sense transistor and the main transistor is affected by manufacturing variations, thereby deviating from a desired size ratio, the ratio between the current from the sense transistor and the drive current of the main transistor may deviate from a desired ratio.

### SUMMARY

An aspect of the present disclosure is an integrated circuit, comprising: a first transistor having an electrode on a high potential side thereof to receive a predetermined voltage, a control electrode to receive a control voltage, and an electrode on a low potential side thereof, the first transistor being configured to send a first current to a load connected to the integrated circuit; a second transistor having an electrode on a high potential side thereof to receive the predetermined voltage, a control electrode to receive the control voltage, and an electrode on a low potential side thereof, the second transistor being configured to send a second current corresponding to the first current; a third transistor connected between the electrode on the low potential side of the second transistor and a predetermined line; an operational amplifier configured to control the third transistor such that a voltage at the electrode on the low potential side of the first transistor and a voltage at the electrode on the low potential side of the second transistor are equal; and a subtractor circuit configured to, in response to a first condition being satisfied, send a third current to a ground, the third current being a part of the second current.

Another aspect of the present disclosure is an integrated circuit, comprising: a first transistor having an electrode on a high potential side thereof to receive a predetermined voltage, and a control electrode to receive a control voltage, and an electrode on a low potential side thereof, the first transistor being configured to send a first current to a load connected to the integrated circuit; a second transistor having an electrode on a high potential side thereof to receive the predetermined voltage, a control electrode to receive the control voltage, and an electrode on a low potential side thereof, the second transistor being configured to send a second current corresponding to the first current; a third transistor connected between the electrode on the low potential side of the second transistor and a predetermined line; an operational amplifier configured to control the third transistor such that a voltage at the electrode on the low potential side of the first transistor and a voltage at the electrode on the low potential side of the second transistor are equal; and an adder circuit configured to add a fourth current to the second current, in response to a predetermined condition being satisfied.

Still another aspect of the present disclosure is an integrated circuit, comprising: a first transistor having an electrode on a high potential side thereof to receive a predetermined voltage, and a control electrode to receive a control voltage, and an electrode on a low potential side thereof, the first transistor being configured to send a first current to a load connected to the integrated circuit; a second transistor having an electrode on a high potential side thereof to receive the predetermined voltage, and a control electrode to receive the control voltage, and an electrode on a low potential side thereof, the second transistor being configured to send a second current corresponding to the first current; a third transistor connected between the electrode on the low potential side of the second transistor and a predetermined line; an operational amplifier configured to control the third transistor such that a voltage at the electrode on the low potential side of the first transistor and a voltage at the electrode on the low potential side of the second transistor are equal; and another transistor connected to the electrode on the low potential side of the second transistor, said another transistor being configured to be controlled by the operational amplifier together with the third transistor; a bias current source configured to generate a bias current corresponding to a current flowing through said another transistor; and an overcurrent detection circuit configured to detect whether the first current is an overcurrent, based on the bias current.

### BRIEF DESCRIPTION OF THE DRAWINGS

FIG. 1 is a diagram for describing an overview of an integrated circuit 1 of a first embodiment.

FIG. 2 is a diagram for describing details of an integrated circuit 1 of a first embodiment.

FIG. 3 is a diagram for describing subtraction in an integrated circuit 1 of a first embodiment.

FIG. 4 is a diagram for describing addition in an integrated circuit 1 of a first embodiment.

FIG. 5 is a diagram for describing details of an integrated circuit 2 of a second embodiment.

FIG. 6 is a diagram for describing an integrated circuit 2 when a correction is not performed.

FIG. 7 is a diagram for describing an integrated circuit 2 when performing addition.

FIG. 8A illustrates simulation results of addition by an integrated circuit 2.

FIG. 8B illustrates simulation results of addition by an integrated circuit 2.

FIG. 9 is a diagram for describing details of an integrated circuit 3 of a modified example.

FIG. 10 is a diagram for describing an overview of an integrated circuit 1a of a third embodiment.

FIG. 11 is a diagram illustrating a configuration example of an overcurrent detection circuit 102.

FIG. 12 is a diagram for describing details of an integrated circuit 1a of a third embodiment.

FIG. 13 is a diagram for describing an overview of an integrated circuit 1b of a fourth embodiment.

FIG. 14 is a diagram illustrating a configuration example of a current source 101b.

FIG. 15 is a diagram for describing an overview of an integrated circuit 1c of a fifth embodiment.

FIG. 16 is a diagram illustrating a configuration example of a current source 101c.

### DETAILED DESCRIPTION

At least following matters will become apparent from the descriptions of the present description and the accompanying drawings.

Hereinafter, embodiments of the present disclosure will be described with reference to the drawings. The same or equivalent constituent elements, members, and the like illustrated in the drawings are given the same reference numerals, and repetitive description is omitted as appropriate.

### First Embodiment

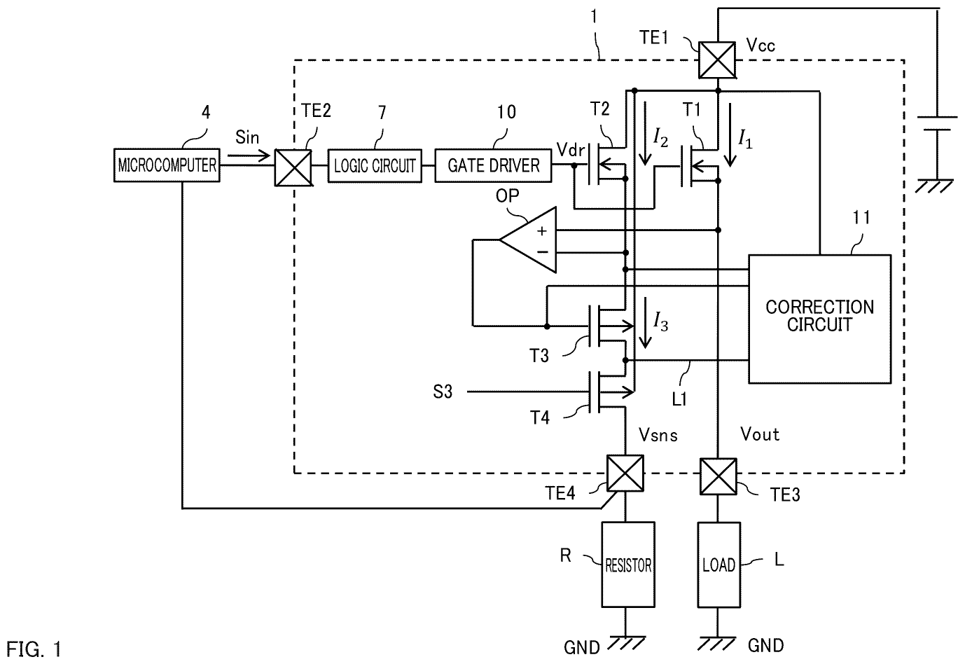

FIG. 1 is a diagram for describing an overview of an integrated circuit 1 of an embodiment of the present disclosure. The integrated circuit 1 is a circuit that drives a load L, in response to a drive signal Sin from a microcomputer 4. The load L is an inductive load such as a motor, for example, but it is not limited thereto. The integrated circuit 1 of an embodiment of the present disclosure includes terminals TE1 to TE4, a logic circuit 7, a gate driver 10, transistors T1 to T3, an operational amplifier OP, and a correction circuit 11.

The terminal TE1 is a terminal to receive a power supply voltage Vcc of the integrated circuit 1 from a power supply external to the integrated circuit 1, and the terminal TE2 is a terminal to receive the signal Sin of a logic level from the microcomputer 4. The terminal TE3 is a terminal to which the load L is connected, and the terminal TE4 is a terminal to which a resistor R is connected.

In an embodiment of the present disclosure, the voltage Vout applied to the load L is applied to the terminal TE3, and a voltage Vsns generated at the resistor R is applied to the terminal TE4. Note that the resistor R corresponds to a so-called sense resistor to detect a current from a transistor T2 (described later).

### (Logic Circuit 7)

The logic circuit 7 receives the control signal Sin transmitted from the microcomputer 4 through the terminal TE2, to thereby generate a logic signal to turn on or off the transistors T1, T2. Upon receiving the control signal of a high level (hereinafter, high or high level) transmitted from the microcomputer 4 through the control signal Sin, the logic circuit 7 outputs a logic signal to turn on the transistors T1, T2.

### (Gate Driver 10)

The gate driver 10 drives each of the transistors T1, T2, in response to the logic signal outputted from the logic circuit 7. Specifically, when the signal Sin is high, the gate driver 10 turns on the transistors T1, T2, and when the signal Sin is low (hereinafter, low or low level), the gate driver 10 turns off the transistors T1, T2.

### (Transistor T1)

The transistor T1 (corresponding to a “first transistor”) is a so-called main transistor to drive the load L. In an embodiment of the present disclosure, the transistor T1 is an n-channel metal-oxide-semiconductor (NMOS) transistor, and has a source electrode, a gate electrode, and a drain electrode.

The gate electrode of the transistor T1 receives a control voltage Vdr from the gate driver 10. A predetermined power supply voltage Vcc (corresponding to a “predetermined voltage”) is applied to the drain electrode of the transistor T1 from the terminal TE1. In an embodiment of the present disclosure, in response to the gate driver 10 turning on the transistor T1, the transistor T1 passes a current I1 (corresponding to a “first current”) through the load L. In the following, the current I1 may be referred to as “load current I1”.

### (Transistor T2)

The transistor T2 (corresponding to a “second transistor”) is a so-called sense transistor that detects the load current I1 by passing a current I2 corresponding to the load current I1 from the transistor T1.

In an embodiment of the present disclosure, the transistor T2 is an NMOS transistor, and has a source electrode, a gate electrode, and a drain electrode.

The gate electrode of the transistor T2 receives the control voltage Vdr from the gate driver 10. The drain electrode of the transistor T2 receives the power supply voltage Vcc from the terminal TE1.

The transistor T2 causes the current I2 (corresponding to a “second current”) according to the load current I1 to flow through the resistor R. The current I2 has a value of, for example, constant times the value of the load current I1. In this case, if the channel length L1 of the transistor T1 and the channel length L2 of the transistor T2 are made the same and the ratio of the channel width W1 of the transistor T1 to the channel width W2 of the transistor T2 is set to, for example, 3000:1, then theoretically the current I2 will be 1/3000 of the value of the load current I1.

In response to the current I2 flowing into the resistor R, the voltage Vsns, which is the product of the resistance R and the current I2, is outputted from the terminal TE4. In this event, the microcomputer 4 detects the voltage Vsns, thereby being able to detect (actually calculate) the current I2.

Upon detecting the current I2, the microcomputer 4 can detect (actually calculate) the load current I1, based on the relationship between the load current I1 and the current I2 described above.

### (Transistor T3)

The transistor T3 (corresponding to a “third transistor”) is a transistor to cause the voltages of the source electrodes of the transistors T1, T2 to be equal to each other (details will be described later in operational amplifier OP).

In an embodiment of the present disclosure, the transistor T3 is a p-channel metal-oxide-semiconductor (PMOS) transistor, and has a source electrode, a gate electrode, and a drain electrode.

The transistor T3 is connected between the source electrode of the transistor T2 and a predetermined line L1 (described later). The gate electrode of the transistor T3 receives the output voltage of the operational amplifier OP (described later).

### (Transistor T4)

The transistor T4 is a transistor to switch between detecting the load current I1 by the transistor T2 and stopping the detection.

In an embodiment of the present disclosure, the transistor T4 is a PMOS transistor, and has a source electrode, a gate electrode, and a drain electrode.

The transistor T4 is connected between the transistor T3 and the terminal TE4. For example, a signal S3 from the microcomputer 4 is inputted to the gate electrode of the transistor T4 through a terminal (not illustrated).

When the signal S3 is low, the load current I1 is detected by the transistor T2. When the signal S3 is high, the detection of the load current I1 by the transistor T2 is stopped.

Note that each back gate of the transistors T1 and T2 receives the voltage equal to that applied to the source electrodes thereof, however, a configuration may be such that it may receive a voltage equal to or lower than that received by each of the source electrodes. Further, each back gate of the transistors T3 and T4 receives the power supply voltage Vcc, however, a configuration may be such that it may receive a voltage equal to or higher than that received by each of the source electrodes.

### (Correction Circuit 11)

The correction circuit 11 is a circuit that corrects the current flowing into the resistor R when the ratio of the load current I1 to the current I2 flowing through the transistor T2 deviates from a design value.

Note that factors that cause the ratio between the load current I1 and the current I2 to deviate from the design value include, for example, manufacturing variations in the size ratio between the transistors T1 and T2. Here, the “size ratio” of the transistor T1 refers to the ratio of the channel length to the channel width (W1/L1) of the transistor, when the transistor T1 is a MOS transistor as in an embodiment of the present disclosure.

If such manufacturing variations exist, the microcomputer 4 may detect a current value deviating from the actual value, and thus may not be able to correctly control the integrated circuit 1 which is to be controlled by the microcomputer.

By virtue of the correction circuit 11, which will be described later in detail, it becomes possible to prevent the ratio between the load current I1 of the transistor T1 to the current I2 of the transistor T2 from deviating from a desired value.

### (Operational Amplifier OP)

The operational amplifier OP controls the correction circuit 11 such that the voltage at the source electrode of the transistor T1 will be equal to the voltage at the source electrode of the transistor T2 (this will be described in detail later).

### <Configuration of Integrated Circuit 1>

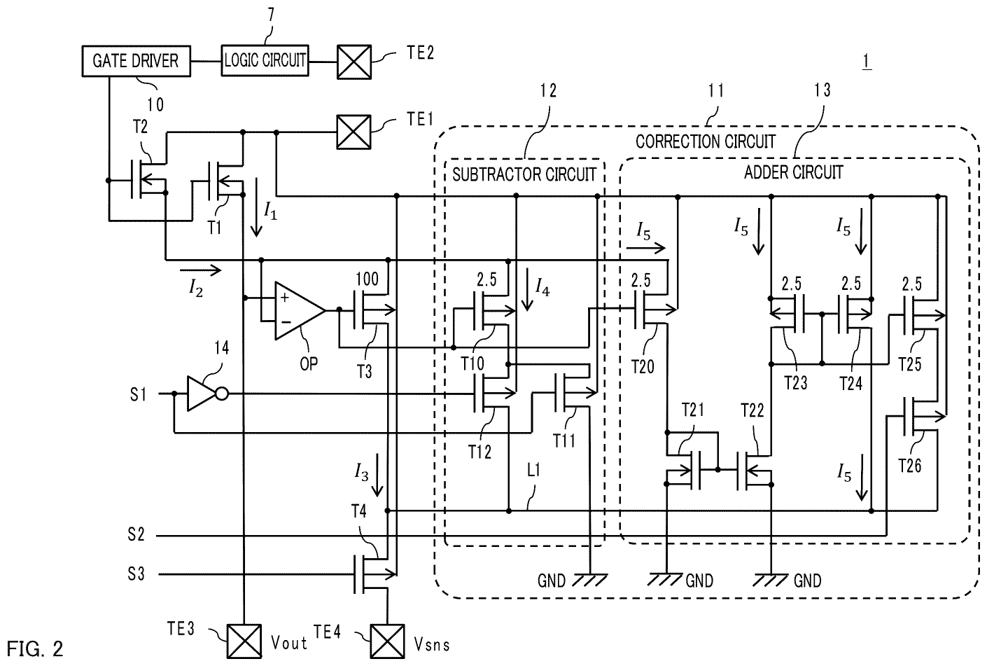

FIG. 2 is a diagram for describing details of the integrated circuit 1 of an embodiment of the present disclosure. The integrated circuit according to an embodiment of the present disclosure includes the transistors T1 to T3, the operational amplifier OP, a subtractor circuit 12, an adder circuit 13, and an inverter 14. Since the transistors T1 to T3 have been described above, the description thereof is omitted below.

Note that the numerical value “100” given to the transistor T3 in FIG. 2 indicates the current flowing through the transistor T3, and is a relative value when the current flowing through the transistor T3 is taken as 100.

### (Operational Amplifier OP)

The operational amplifier OP controls the transistor T3 such that the voltage at the source electrode of the transistor T1 will be equal to the voltage at the source electrode of the transistor T2.

The operational amplifier OP has a non-inverting input terminal connected to the source electrode of the transistor T1, an inverting input terminal connected to the source electrode of the transistor T2, and an output terminal connected to the gate electrode of the transistor T3.

The operational amplifier OP controls the transistor T3 such that the voltage at the source electrode of the transistor T2 applied to the inverting input terminal will reach the voltage at the source electrode of the transistor T1 applied to the non-inverting input terminal.

### ((Subtractor Circuit 12))

The subtractor circuit 12 is a circuit that subtracts a current of a predetermined value from the current flowing into the resistor R in FIG. 1, when the ratio of the load current I1 to the current I2 flowing through the transistor T2 (I1/I2) decreases below the design value due to manufacturing variations in the integrated circuit 1 (hereinafter, this may be simply referred to as “subtraction”).

By performing subtraction, the difference between the actual load current I1 and the detected load current I1 can be reduced.

When performing subtraction, the subtractor circuit 12 passes a current I4 (corresponding to a “third current”), which is a part of the current I2, to the ground GND. The following describes the details.

The subtractor circuit 12 includes transistors T10 to T12 and the inverter 14.

### (Transistor T10)

The transistor T10 (corresponding to a “fourth transistor”) is a PMOS transistor in an embodiment of the present disclosure, and has a source electrode, a gate electrode, and a drain electrode.

The output voltage of the operational amplifier OP is applied to the gate electrode of the transistor T10. The source electrode of the transistor T10 is connected to the source electrode of the transistor T2.

The numerical value “2.5” given to the transistor T10 in FIG. 2 indicates the current I3 flowing through the transistor T10, and is a relative value when the current flowing through the transistor T3 is taken as 100.

The same relative values are given to other transistors T10, T20, T23, T24, and T25, which will be described later, as to the currents flowing therethrough. Note that the relative value of the current that flows when a transistor T26, which will be described later, is on is given to the transistor T25.

For example, by making the channel lengths of the transistors T3 and T10 equal and then setting the ratio between the channel widths thereof to 100:2.5, it is possible to set the ratio of the currents flowing therethrough to 100:2.5.

### (Transistor T11)

The transistor T11 (corresponding to a “first switch”) is a PMOS transistor in an embodiment of the present disclosure, and has a source electrode, a gate electrode, and a drain electrode.

The transistor T11 is located between the drain electrode of the transistor T10 and the ground GND. The gate electrode of the transistor T11 is connected to the inverter 14 (described later).

### (Transistor T12)

The transistor T12 (corresponding to a “second switch”) is a PMOS transistor in an embodiment of the present disclosure, and has a source electrode, a gate electrode, and a drain electrode.

The transistor T12 is turned off when the subtractor circuit 12 performs subtraction. Further, the transistor T12 is turned on when the subtractor circuit 12 does not perform subtraction. That is, the transistors T11, T12 are turned on and off complementarily (details will be described later).

### (Inverter 14)

The inverter 14 (corresponding to a “switch control circuit”) complementarily turns on and off the transistors T11, T12.

A signal S1 is inputted to the inverter 14. When the signal S1 is high, the transistor T11 is off and the transistor T12 is on. Further, when the signal S1 is low, the transistor T11 is on and the transistor T12 is off.

When the subtractor circuit 12 performs subtraction, the signal S1 is set to low, and when the subtraction circuit 12 does not perform subtraction, the signal S1 is set to high, which will be described in detail below.

### ((Adder Circuit 13))

The adder circuit 13 is a circuit that adds the current having a predetermined value to the current flowing through the resistor R in FIG. 1, when the ratio of the load current I1 flowing through the transistor T1 to the current I2 flowing through the transistor T2 (I1/I2) exceeds the design value, due to manufacturing variations in the integrated circuit 1 (hereinafter, this may be simply referred to as “addition”).

By performing addition, it is possible to reduce the difference between the actual load current I1 and the detected load current I1.

When performing addition, the adder circuit 13 adds a current I6 (corresponding to a “fourth current”) to the current I2.

The adder circuit 13 includes transistors T20 to T26.

### (Transistor T20)

The transistor T20 (corresponding to a “fifth transistor”) is a PMOS transistor in an embodiment of the present disclosure, and has a source electrode, a gate electrode, and a drain electrode.

The output voltage of the operational amplifier OP is applied to the gate electrode of the transistor T20. The source electrode of the transistor T20 is connected to the source electrode of the transistor T2.

### (Transistors T21, T22)

In an embodiment of the present disclosure, the transistors T21, T22 are both PMOS transistors, and each have a source electrode, a gate electrode, and a drain electrode.

The transistor T21 is connected between the transistor T20 and the ground GND, and is diode-connected. The transistor T22 is connected between the transistor T23 (described later) and the ground GND.

The transistors T21, T22 have a size ratio of 1:1. The transistors T21, T22 configure a current mirror circuit. Accordingly, a current I5 that is the same as the current I5 that flows through the transistor T21 via the transistor T20 flows through the transistor T22 via the transistor T23 (described later).

### (Transistors T23, T24)

In an embodiment of the present disclosure, the transistors T23, T24 are both PMOS transistors, and each have a source electrode, a gate electrode, and a drain electrode.

The transistor T23 is connected between the terminal TE1 and the transistor T22, and is diode-connected. The transistor T24 is connected between the terminal TE1 and the line L1.

The transistors T23, T24 have a size ratio of 1:1. The transistors T23, T24 configure a current mirror circuit.

Accordingly, the current I5 that is the same as the current I5 that flows through the transistor T23 described above flows through the transistor T24.

### (Transistor T25)

The transistor T25 (corresponding to a “sixth transistor”) is a PMOS transistor in an embodiment of the present disclosure, and has a source electrode, a gate electrode, and a drain electrode.

The transistor T25 is connected between the terminal TE1 and the transistor T26 (described later). The gate electrode of the transistor T25 is connected to the gate electrode of the diode-connected transistor T23.

Accordingly, the transistors T25, T23 configure a current mirror circuit. The transistor T25 produces the current I6 corresponding to the current flowing through the transistor T23.

Note that in an embodiment of the present disclosure, the transistors T25, T23 are the transistors with a size ratio of 1:1.

### (Transistor T26)

The transistor T26 (corresponding to a “third the switch”) is a PMOS transistor in an embodiment of the present disclosure, and has a source electrode, a gate electrode, and a drain electrode.

The transistor T26 is located between the transistor T25 and the line L1. A signal S2 is inputted to the gate electrode of the transistor T26. The transistor T26 is turned on and off in response to the signal S2.

When the adder circuit 13 performs addition, the signal S2 is set to low, and when the adder circuit 13 does not perform addition, the signal S2 is set to high, which will be described in detail below.

The integrated circuit 1 according to an embodiment of the present disclosure has been described above. In the following, subtraction and addition in the integrated circuit 1 are described.

### <Subtraction>

Subtraction in the integrated circuit 1 according to an embodiment of the present disclosure will be described. Subtraction is performed when the ratio of the load current I1 to the current I2 flowing through the transistor T2 (I1/I2) decreases below the designed value due to manufacturing variations in the transistors T1, T2.

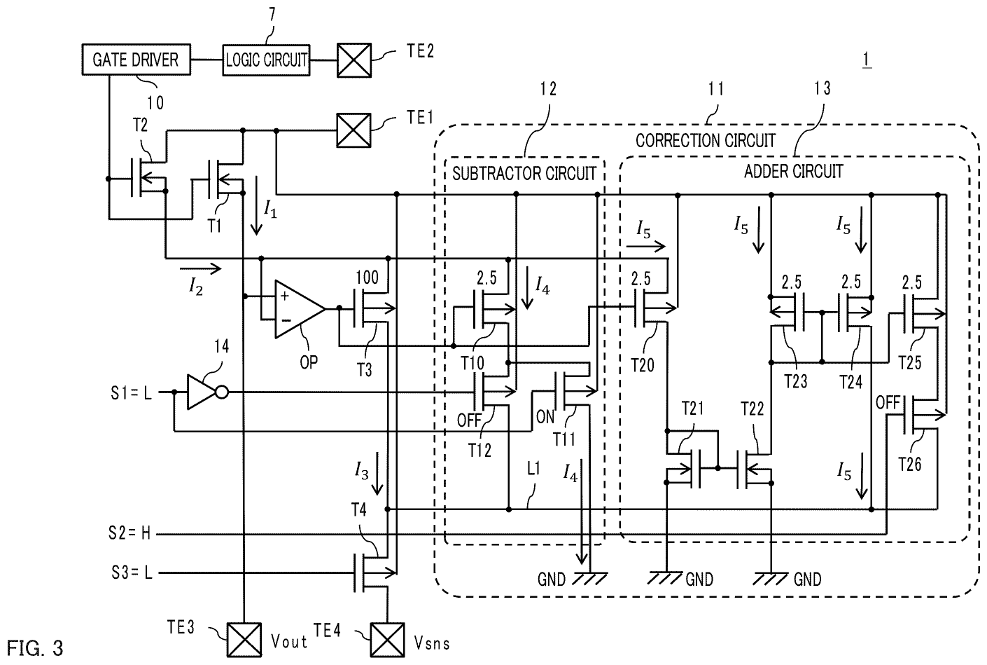

FIG. 3 illustrates subtraction in the integrated circuit 1 of an embodiment of the present disclosure. When subtraction is performed, the signals S1 and S2 are set to low and high, respectively. Note that the case in which the signals S1 and S2 are low and high, respectively, corresponds to the case “when a first condition is satisfied”.

The value of the current flowing into the line L1 (i.e., current value) in this case will be described below. In the following description, the current values of the aforementioned currents I1 to I6 are given I1 to I6, respectively.

As illustrated in FIG. 3, in the case of subtraction, the transistor T11 is on, the transistor T12 is off, and the transistor T26 is off.

Accordingly, in the case of subtraction, the value of the current flowing into the line L1 is the sum of the current values of the currents flowing thereinto from the transistor T3 and the transistor T24.

The current value I3 of the current flowing into the line L1 from the transistor T3 is I2-I4-I5. Further, the value of the current flowing from the transistor T24 to the line L is I5.

Accordingly, in the case of subtraction, the current flowing into the line L1 is I2-I4. That is, the current flowing into the resistor R through the line L1 can be subtracted, by an amount corresponding to the current I4, from the current I2 flowing through the transistor T2.

In an embodiment of the present disclosure, the ratio between the current I2 and the current I4 is 105:2.5. Accordingly, 1/42 of the current I2 can be subtracted from the current I2.

Note that the amount of correction for subtraction with respect to the current I2 can be a desired amount by adjusting the current I4. The current I4 can be adjusted by adjusting the channel width of the transistor T10, for example.

### <Addition>

Addition in the integrated circuit 1 of an embodiment of the present disclosure will be described. Addition is performed when the ratio of the load current I1 flowing through the transistor T1 to the current I2 flowing through the transistor T2 (I1/I2) exceeds the designed value due to manufacturing variations in the transistors T1, T2.

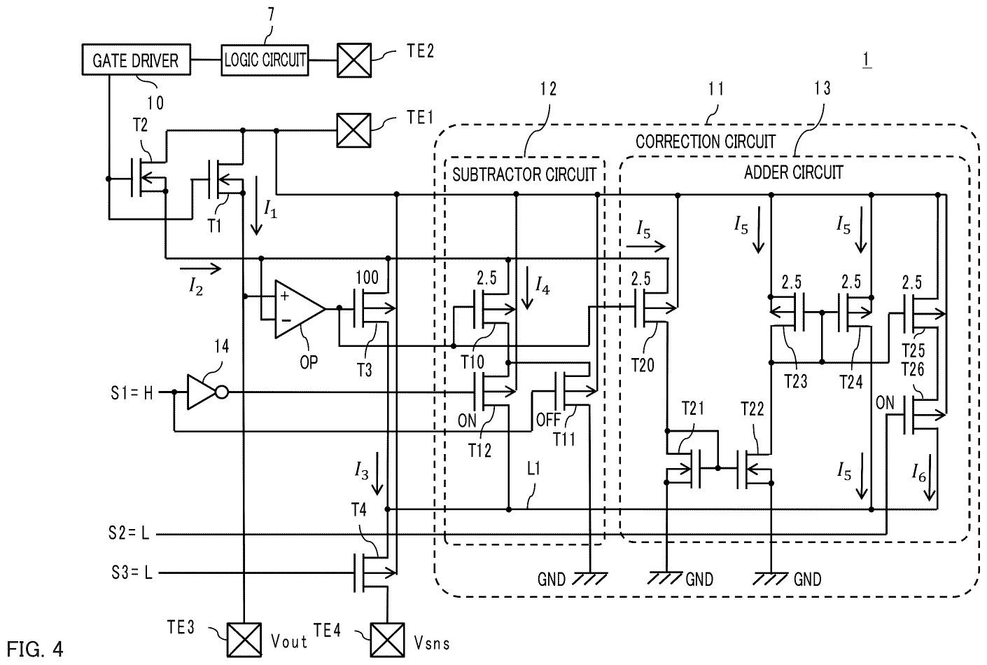

FIG. 4 illustrates addition in the integrated circuit 1 of an embodiment of the present disclosure. When addition is performed, the signals S1 and S2 are set to high and low, respectively. Note that the case in which the signals S1 and S2 are high and low, respectively, corresponds to the case “when a second condition is satisfied”.

The value of the current flowing into the line L1 in this case will be described. As illustrated in FIG. 4, in the case of addition, the transistor T11 is off, the transistor T12 is on, and the transistor T26 is on.

Accordingly, in the case of addition, the value of the current flowing into the line L1 is the sum of the values of the currents flowing from the transistor T3, the transistor T10, the transistor T24, and the transistor T25.

The value of the current flowing into the line L1 from the transistor T3 is I2-I4-I5. Further, the value of the current flowing into the line L1 from the transistor T10 is I4. Further, the value of the current flowing into the line L1 from the transistor T24 is I5. Further, the value of the current flowing into the line L1 from the transistor T25 is I6.

Accordingly, in the case of addition, the value of the current flowing into the line L1 is I2+I6. That is, the current flowing into the resistor R through the line L1 can be added, by an amount corresponding to the current I6, to the current I2 flowing through the transistor T2.

In an embodiment of the present disclosure, the ratio of the current I2 to the current I6 is 105:2.5. Accordingly, 1/42 of the current I2 can be added to the current I2.

The amount of correction for addition with respect to the current I2 can be a desired amount by adjusting the current I6. The current I6 can be adjusted by adjusting the channel width of the transistor T25, for example.

According to the integrated circuit 1 described above, it is possible to perform one-step subtraction and one-step addition with respect to the current flowing into the resistor R. This makes it possible to suppress deviation of the ratio between the load current I1 from the transistor T1 and the current flowing into the resistor R, from the desired value.

In an embodiment of the present disclosure, it is assumed that the current I4 and the current I6 have the same current value (2.5 when the current I3 is taken as 100), but this is not limited thereto, and the current values of the current I4 and the current I6 may be different.

This makes it possible to perform three-step subtraction or addition, in response to the signals S1 and S2.

Specifically, when both the subtractor circuit 12 and the adder circuit 13 are to be operated (signal S1=low, signal S2=low), it is also possible to perform subtraction or addition with the amount of correction as I6−I4 (≠0).

Further, in an embodiment of the present disclosure, it is assumed that the transistors T1 to T3, T10 to T12, T20 to T26 are MOS transistors, however, they are not limited thereto, and other types of transistors, such as IGBTs, may be used instead.

Each “drain electrode” of the transistors T1, T2, T21, and T22 is an example of an “electrode on a high potential side”, the “gate electrode” thereof is an example of a “control electrode”, and the “source electrode” is an example of an “electrode on a low potential side”.

Further, the “source electrode” of the transistors T3, T10 to T12, T20, T23 to T26 is an example of the “electrode on the high potential side”, the “gate electrode” thereof is an example of the “control electrode”, and the “drain electrode” is an example of the “electrode on the low potential side”.

### Second Embodiment

The integrated circuit 1 of the first embodiment is able to perform one-step subtraction and one-step addition. In an embodiment of the present disclosure, an integrated circuit 2 capable of performing many more steps of subtraction or addition will be described.

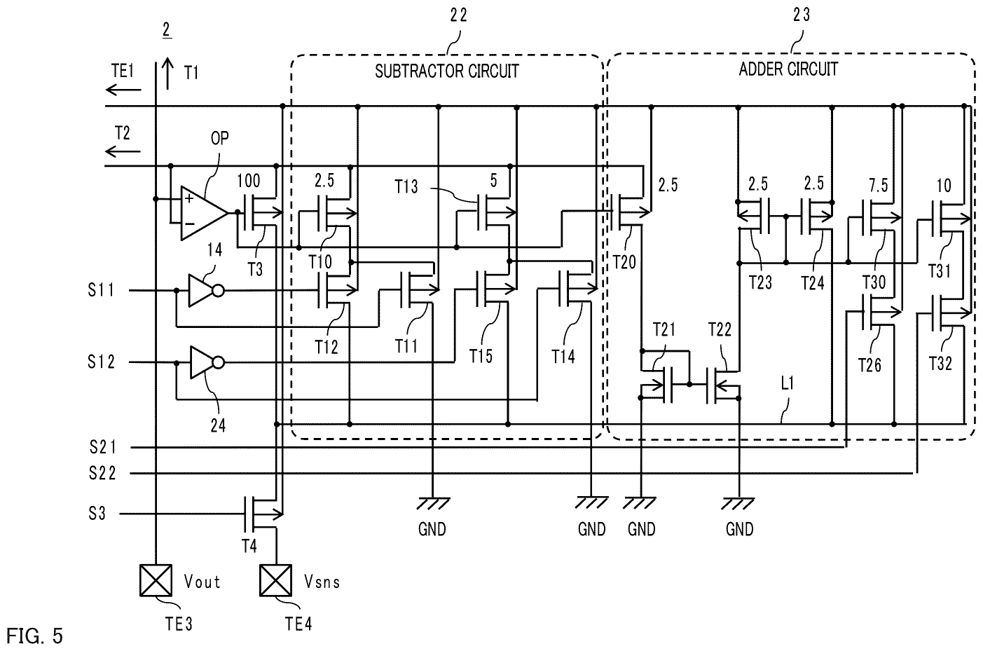

FIG. 5 illustrates the details of the integrated circuit 2 of an embodiment of the present disclosure. The integrated circuit 2 is different from the integrated circuit of the first embodiment in the subtractor circuit 22 and the adder circuit 23. Further, the integrated circuit 2 further includes the inverter 24.

### (Subtractor Circuit 22)

The subtractor circuit 22 differs from the subtractor circuit 12 of the first embodiment (FIG. 2) in further including the transistors T13 to T15.

### (Transistor T13)

The transistor T13 is a PMOS transistor in an embodiment of the present disclosure, and has a source electrode, a gate electrode, and a drain electrode.

The output voltage of the operational amplifier OP is applied to the gate electrode of the transistor T13. The source electrode of the transistor T13 is connected to the source electrode of the transistor T2. In other words, the transistor T13 is connected in parallel with the transistor T10.

Further, the relative amount of the current flowing through the transistor T10 is 2.5, while the relative amount of the current flowing through the transistor T13 is 5.0.

### (Transistor T14)

The transistor T14 is a PMOS transistor in an embodiment of the present disclosure, and has a source electrode, a gate electrode, and a drain electrode.

The transistor T14 is located between the drain electrode of the transistor T13 and the ground GND. The gate electrode of the transistor T14 is connected to the inverter 24 (described below).

### (Transistor T15)

The transistor T15 is a PMOS transistor in an embodiment of the present disclosure, and has a source electrode, a gate electrode, and a drain electrode.

The transistor T15 is located between the transistor T13 and the line L1. The gate electrode of the transistor T15 is connected to the inverter 24 (described below).

### (Inverter 24)

The inverter 24 turns on and off the transistors T14, T15 complementarily. A signal S12 is inputted to the inverter 24. When the signal S12 is high, the transistor T14 is off and the transistor T15 is on. When the signal S12 is low, the transistor T14 is on and the transistor T15 is off.

### ((Adder Circuit 23))

The adder circuit 23 differs from the adder circuit 13 of the first embodiment in including the transistor T30 in place of the transistor T25 and further including the transistors T31, T32.

### (Transistor T30)

The transistor T30 is provided in place of the transistor T25 in the first embodiment. They are different only in that the relative amount of the current flowing through the transistor T25 is 2.5, while the relative amount of the current flowing through the transistor T30 is 7.5.

### (Transistor T31)

The transistor T31 is a PMOS transistor in an embodiment of the present disclosure, and has a source electrode, a gate electrode, and a drain electrode.

The transistor T31 is connected between the terminal TE1 and the transistor T32 (described below). The gate electrode of the transistor T31 is connected to the gate electrode of the diode connected transistor T23.

Accordingly, the transistors T31, T23 configure a current mirror circuit. The transistor T31 produces a current corresponding to the current flowing through the transistor T23. As illustrated in FIG. 5, the relative value of the current that the transistor T31 is to produce is 10.

Note that in an embodiment of the present disclosure, the size ratio between the transistor T30 and the transistor T23 is 3:1 and the size ratio between the transistor T31 and the transistor T23 is 4:1.

### (Transistor T32)

The transistor T32 is a PMOS transistor in an embodiment of the present disclosure, and has a source electrode, a gate electrode, and a drain electrode.

The transistor T32 is located between the transistor T31 and the line L1. A signal S22 is inputted to the gate electrode of the transistor T32. The transistor T32 turns on and off, in response to the signal S22.

The configuration of the integrated circuit 2 according to an embodiment of the present disclosure has been described above. According to the integrated circuit 2 of an embodiment of the present disclosure, it is possible to perform ten-step subtraction or ten-step addition, in response to the signals S11, 512, 521, S22.

The case in which all of the signals 511, 512, 521, and S22 are high is excluded from the 10 steps here. In this case, neither subtraction nor addition is performed.

In the following, one addition out of the ten steps of subtraction or addition in the integrated circuit 2 will be described as compared with the case in which correction is not made.

First, with or without correction, the current flowing through the transistor T2 is the sum of the currents flowing through the transistors T3, T10, T13, and T20. Accordingly, the relative value of the current flowing through the transistor T2 is 110.0 (=100.0+2.5+5.0+2.5).

### <When Correction is not Made>

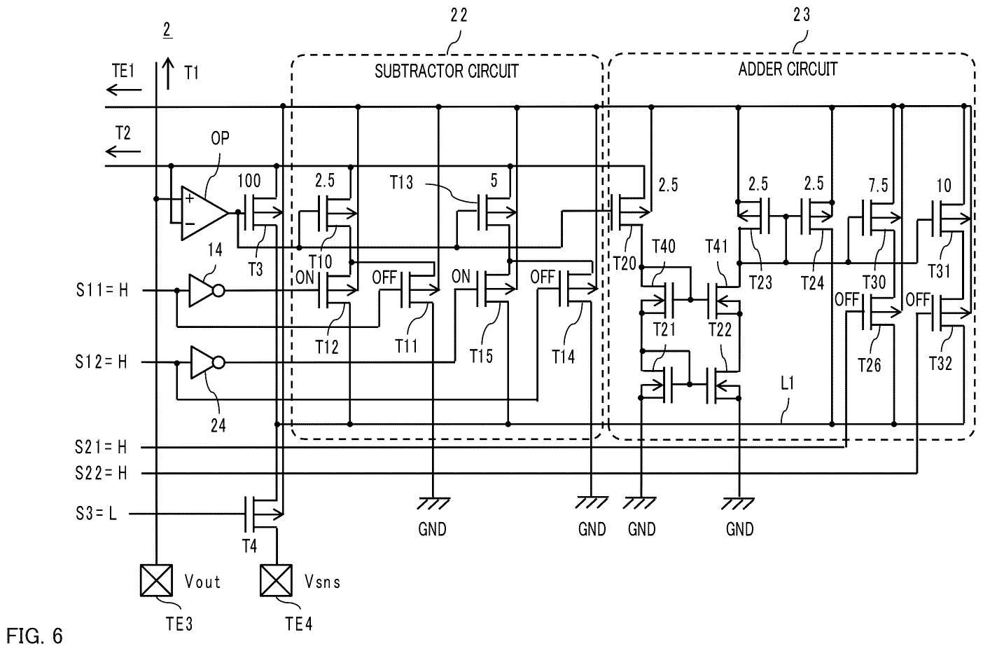

FIG. 6 illustrates the integrated circuit 2 when correction is not made. When correction is not made, all of the signals S11, S12, S21, and S22 are high.

In this case, as illustrated in FIG. 6, the transistor T11 is off, the transistor T12 is on, the transistor T14 is off, the transistor T15 is on, the transistor T26 is off, and the transistor T32 is off.

Accordingly, in this case, the current flowing into the line L1 is the sum of the currents flowing through the transistor T3, the transistor T10, the transistor T13, and the transistor T24. That is, the relative value of the current flowing into the line L1 is 110 (=100+2.5+5.0+2.5).

That is, the relative value of the current flowing into the line L1 is the same as the relative value of the current flowing through the transistor T2, and is not corrected.

### <Addition>

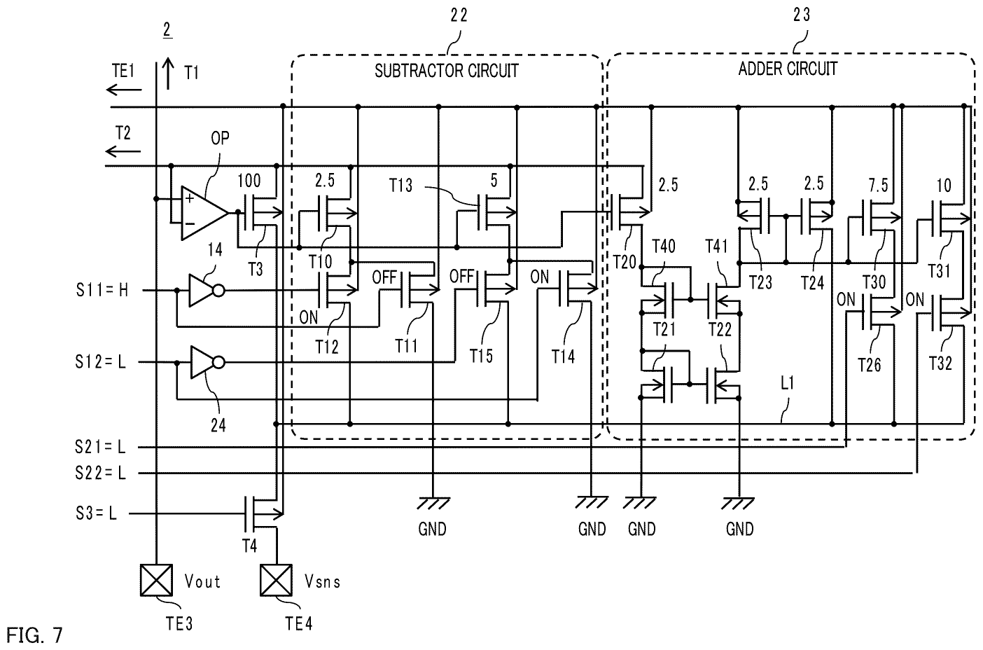

FIG. 7 illustrates the integrated circuit 2 when addition is performed. In the case of addition in this figure, the signal S11 is high, the signal S12 is low, the signal S21 low, and the signal S22 low.

In this case, as illustrated in FIG. 7, the transistor T11 is off, the transistor T12 is on, the transistor T14 is on, the transistor T15 is off, the transistor T26 is on, and the transistor T32 is on.

Accordingly, in this case, the current flowing through the line L1 is the sum of the currents flowing into the transistor T3, the transistor T10, the transistor T24, the transistor T30, and the transistor T31. That is, the relative value of the current flowing into the line L1 is 122.5 (=100.0+2.5+2.5+7.5+10.0).

This means that the relative value of the current flowing into the line L1 is obtained by adding 11.4% (=(122.5−110.0)/110.0) to the relative value of the current flowing into the transistor T2 (110.0).

In the following, simulation results are used to describe how much error with respect to the ideal value of the current flowing into the resistor R is reduced by the addition described above.

### <Simulation Results>

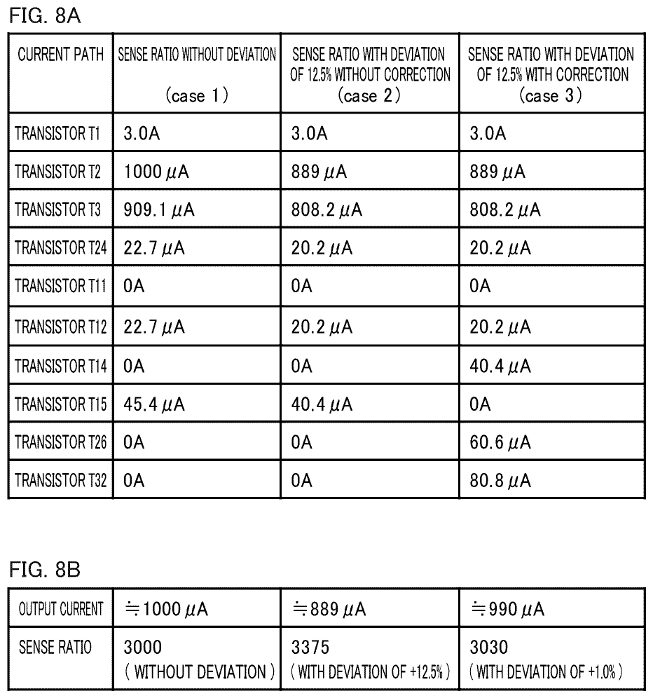

FIGS. 8A and 8B illustrate the simulation results of addition performed by the integrated circuit 2. In this simulation, it is assumed that the current I2 flowing through the transistor T2 deviates from the designed value due to manufacturing variations.

The following firstly describes the results in the order as follows: the ideal case without manufacturing variations (case 1), the case in which manufacturing variations cause deviation but correction is not made (case 2), and the case in which manufacturing variations cause deviation and correction is made (case 3).

FIG. 8A illustrates the currents flowing through the transistors given in a first column. In FIG. 8B, the term “output current” refers to the current flowing into the line L1 (i.e., the current flowing into the resistor R). Further, the “sense ratio” is a value obtained by dividing the load current I1 flowing through the transistor T1 by the output current.

### (Ideal Case (Case 1))

In FIGS. 8A and 8B, a second column gives a result of the ideal case (without deviation). In the case 1, the current value I1 flowing through the transistor T1 is 3.0 A and the current value I2 flowing through the transistor T2 is 1000 μA.

In the case 1, the current value I2 flows into the resistor R as it is, and thus the output current results in 1000 μA. Accordingly, the sense ratio in this case is 3000.

### (When Deviation Occurs but Correction is not Made (Case 2)}

In FIGS. 8A and 8B, a third column gives the results when deviation from the ideal value occurs in the current value I2 and correction is not made. That is, this is when assuming that all of the signals S11, S12, S21, and S22 are high in the integrated circuit 2.

In this case, the current value I2 flowing through the transistor T2 is 889 μA, which is less than that in the case 1 (1000 μA) by only 111 μA. In the case 2 as well, the current value I2 flows into the resistor R as it is, and thus the output current is 889 μA.

Accordingly, the sense ratio in this case is 3375 (=3.0 A/889 μA), resulting in occurrence of a deviation of +12.5% from that in the case 1.

### (When Deviation Occurs and Correction is Made (Case 3))

In FIGS. 8A and 8B, a fourth column illustrates a result when the same deviation as in the case 2 occurs in the current value I2, and the addition described above is performed.

In this case, the current I2 flowing through the transistor T2 is 889 μA, which is the same as in the case 2.

However, in accordance with the addition described above, the current obtained by adding +11.4% to the current I2 flows into the resistor R. In this case, the current (output current) flowing into the resistor R is 990 μA (≈889 μA×(100%+11.4%)).

Accordingly, the sense ratio in this case is 3030 (=3.0 A/990 μA), and the deviation from that in the case 1 is +1.0%. That is, it can be seen that the addition described above is able to reduce the deviation of the sense ratio as compared with the case 2.

### Modified Examples

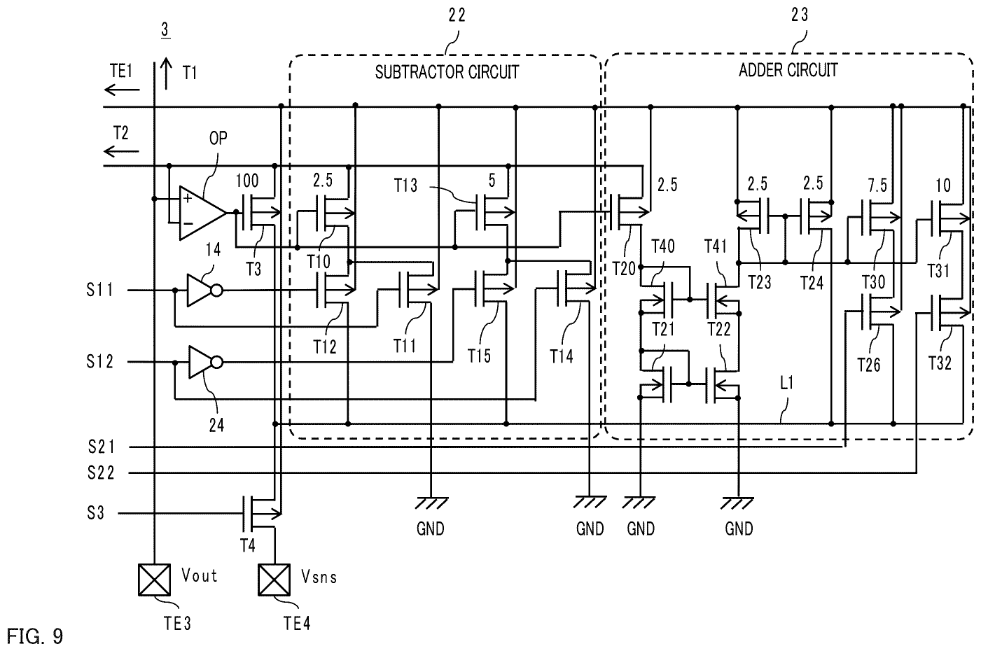

FIG. 9 illustrates the details of an integrated circuit 3 of a modified example. As compared to the second embodiment (FIG. 5), the integrated circuit 3 of the modified example is different in further including cascode-connected transistors T40, T41 with respect to the transistors T21, T22.

Such a configuration can suppress an error with respect to the ideal value of the current to be copied, when the channel length modulation effect occurs in the transistors T21, T22, which configure a current mirror circuit.

Note that the back gate of the NMOS transistor constituting the correction circuit 11 in an embodiment described above receives the voltage equal to that at the source electrode thereof, however, a configuration may be such that it may receive a voltage equal to or lower than the voltage applied to each source electrode thereof. Further, the back gate of the PMOS transistor constituting the correction circuit 11 in an embodiment described above receives the power supply voltage Vcc, however, a configuration may be such that it may receive a voltage equal to or higher than the voltage applied to each source electrode.

### Third Embodiment

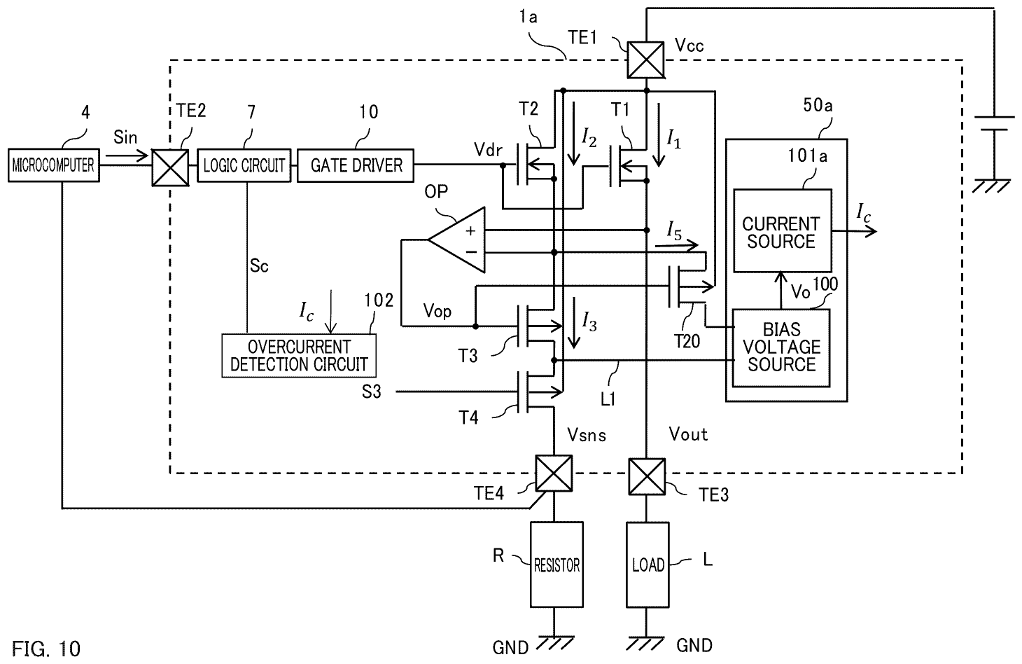

FIG. 10 is a diagram for describing an overview of an integrated circuit 1a of a third embodiment. The integrated circuit 1a is a circuit that drives the load L, in response to the drive signal Sin from the microcomputer 4. The integrated circuit 1a of the third embodiment has the terminals TE1 to TE4, the logic circuit 7, the gate driver 10, the transistor T1 to T4, T20, the operational amplifier OP, a bias current source 50a which includes a bias voltage source 100 and a current source 101a, and an overcurrent detection circuit 102. The terminals TE1 to TE4, the logic circuit 7, the gate driver 10, and the transistors T1 to T4 have the same configurations and operations as those in the first embodiment illustrated in FIG. 1, and thus the description thereof is omitted.

### (Transistor T20)

The transistor T20 (corresponding to a “transistor”) is a PMOS transistor in the third embodiment, and has a source electrode, a gate electrode, and a drain electrode.

The output voltage Vop of the operational amplifier OP is applied to the gate electrode of the transistor T20, as in the transistor T3. The source electrode of the transistor T20 is connected to the source electrode of the transistor T2.

### (Bias Current Source 50a)

The bias current source 50a includes the bias voltage source 100 and the current source 101a, and passes a bias current IC corresponding to the current flowing through the transistor T20.

### (Bias Voltage Source 100)

The bias voltage source 100 generates a bias voltage Vo corresponding to the current flowing through the transistor T20, which will be described in detail below.

### (Current Source 101a)

The current source 101a passes the bias current IC, based on the bias voltage Vo, which will be described in detail below.

### (Overcurrent Detection Circuit 102)

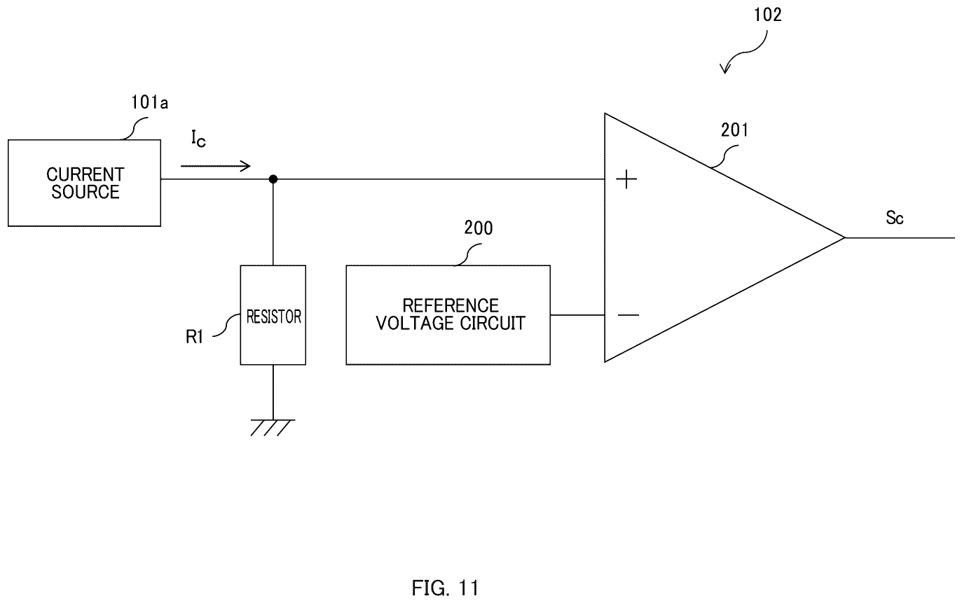

The overcurrent detection circuit 102 detects whether the current I1 is overcurrent, based on the bias current IC. The overcurrent detection circuit 102 includes a resistor R1, a reference voltage output circuit 200, and a comparator circuit 201, as illustrated in FIG. 11.

The bias current IC from the current source 101a flows through the resistor R1, and the reference voltage output circuit 200 outputs a reference voltage to detect whether the current I1 is overcurrent. The comparator circuit 201 then compares the voltage generated at the resistor R1 with the reference voltage, to thereby detect whether the current I1 is overcurrent.

Upon detecting that the current I1 is overcurrent, the overcurrent detection circuit 102 outputs a high signal Sc to the logic circuit 7, and upon detecting that the current I1 is not overcurrent, it outputs a low signal Sc to the logic circuit 7. Further, responsive to the overcurrent detection circuit 102 outputting the high signal Sc, the logic circuit 7 generates a signal to turn off the transistors T1, T2, and output the signal to the gate driver 10.

Whether the current flowing through the transistor T1 is overcurrent has been detected based on the drain-source voltage of the transistor T1. However, due to the positive temperature characteristics of the on-resistance of the transistor T1, the current value for detecting that the current I1 flowing through the transistor T1 is overcurrent could decrease, with a rise in the temperature.

Meanwhile, as in an embodiment of the present disclosure, by using the current IC to detect whether the current I1 is overcurrent, the current I1 flowing through the transistor T1 is no longer affected by the positive temperature characteristics of the on-resistance of the transistor T1, and the current value for detecting that the current I1 flowing through the transistor T1 is overcurrent results in being constant.

<Configuration of Integrated Circuit 1a>

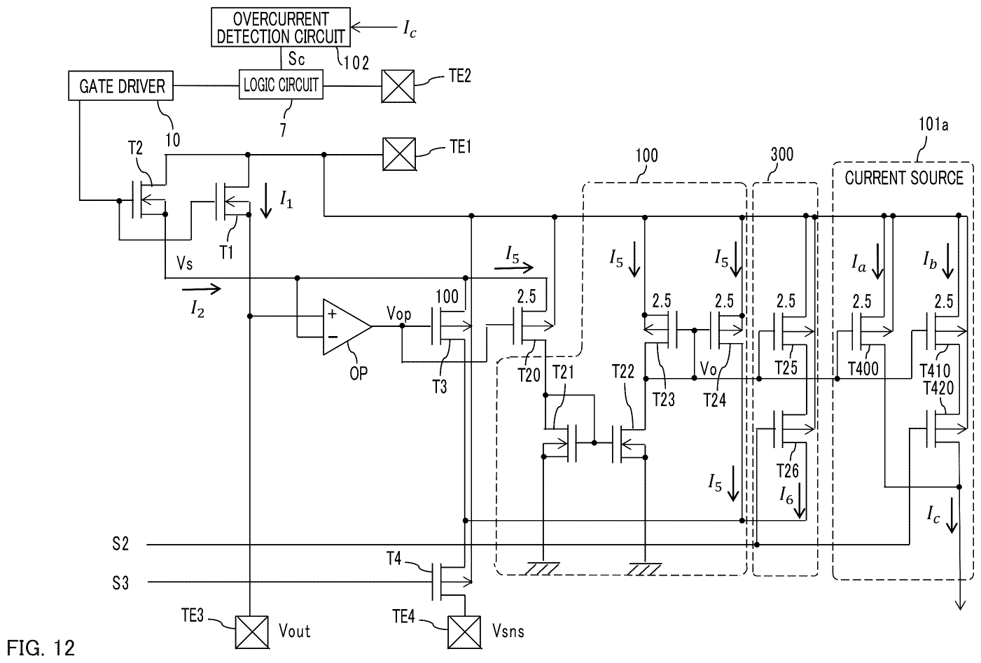

FIG. 12 is a diagram obtained by further adding a first adder circuit 300 to the integrated circuit 1a of an embodiment of the present disclosure. The integrated circuit 1a of an embodiment of the present disclosure includes the transistors T1 to T4, T20, the operational amplifier OP, the bias Voltage Source 100, the current source 101a, and the overcurrent detection circuit 102.

### (Bias Voltage Source 100)

The bias voltage source 100 includes multiple current mirror circuits, and outputs the gate voltage of the current mirror circuit in the last stage as the bias voltage Vo, which corresponds to the current I5 passed by the transistor T20.

The bias voltage source 100 includes a first current mirror circuit including the transistors T21, T22 and a second current mirror circuit including the transistors T23, T24. Note that the gate voltages of the transistors T23, T24 are outputted as the bias voltage Vo.

### (Current Source 101a)

The current source 101a passes the bias current IC corresponding to the current I1, based on the bias voltage Vo corresponding to the current I5 passed by the transistor T20. The current source 101a includes transistors T400, T410, and T420. Note that the numerical value “2.5” given to the transistor T400 in FIG. 12 is a relative value when the current flowing through the transistor T3 is taken as 100. Further, the numerical value “2.5” given to the transistor T410 is a relative value when the current flowing through the transistor T400 is taken as 100. Thus, in an embodiment of the present disclosure, the current Ib flowing through the transistor T410 is 0.0625% of the current I3 flowing through the transistor T3.

### (Transistor T400)

The transistor T400 is a PMOS transistor in an embodiment of the present disclosure, and has a source electrode, a gate electrode, and a drain electrode.

The transistor T400 has the source electrode connected to the terminal TE1, the gate electrode to receive the bias voltage Vo, and the drain electrode to pass the current Ia having a current value corresponding to the value of the current flowing through the transistor T3. In this example, the value of the current Ia is the same as the value of the current flowing through the transistor T23.

### (Transistor T410)

The transistor T410 is a PMOS transistor in an embodiment of the present disclosure, and has a source electrode, a gate electrode, and a drain electrode.

The transistor T410 has the source electrode connected to the terminal TE1, and the gate electrode to receive the bias voltage Vo, and passes the current Ib having a current value corresponding to the value of the current flowing through the transistor T25. In an embodiment of the present disclosure, the value of the current Ib is 1/40 times the current flowing through the transistor T25.

### (Transistor T420)

The transistor T420 is a PMOS transistor in an embodiment of the present disclosure, and has a source electrode, a gate electrode, and a drain electrode.

The transistor T420 is provided between the transistor T410 and the overcurrent detection circuit 102, and the voltage corresponding to the signal S2 is applied to the gate electrode of the transistor T420. The drain electrode thereof is connected to the drain electrode of the transistor T400. Further, the transistor T420 is off when the signal S2 is high and is on when the signal S2 is low.

Accordingly, when the signal S2 is high, the current source 101a passes the current Ia as the bias current Ic. In this case, the current source 101a passes the bias current Ic corresponding to the current value of the current flowing through the transistor T3.

Further, when the signal S2 is low, the current source 101a passes, as the bias current Ic, the current obtained by adding the current Ib to the current Ia. In this case, the current source 101a passes the bias current Ic having a current value obtained by adding the current corresponding to the current flowing through the transistor T3 and the current Ib corresponding to the current I6 flowing through the transistor T25.

That is, the current source 101a changes the current value of the bias current IC in two stages, and passes the bias current Ic having a current value corresponding to the value of the current flowing through the resistor R.

### (First Adder Circuit 300)

The first adder circuit 300 includes the transistors T25, T26. The configurations and operations of the transistors T25, T26 are as with those in the first embodiment, and thus description thereof is omitted.

### Fourth Embodiment

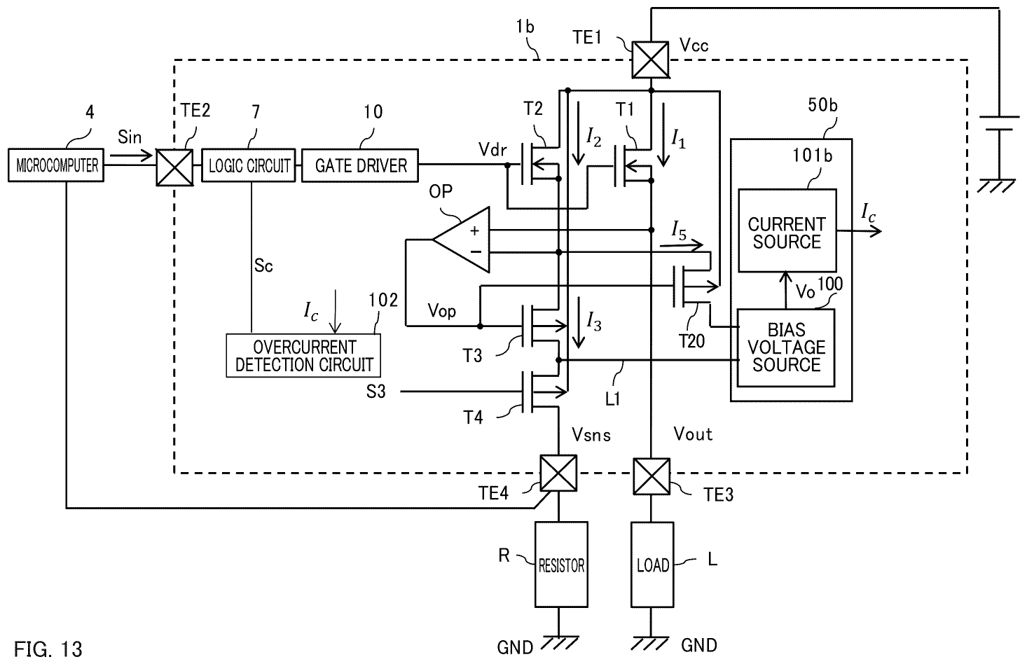

FIG. 13 is a diagram for describing an overview of an integrated circuit 1b of a fourth embodiment. The integrated circuit 1b is a circuit that drives the load L, in response to the drive signal Sin from the microcomputer 4. The integrated circuit 1b of the fourth embodiment includes the terminals TE1 to TE4, the logic circuit 7, the gate driver 10, the transistors T1 to T4, T20, a bias current source 50b, which includes the bias voltage source 100 and a current source 101b, and the overcurrent detection circuit 102. The configurations and operations of the components other than the current source 101b are as with those in the third embodiment illustrated in FIG. 10, description thereof is omitted.

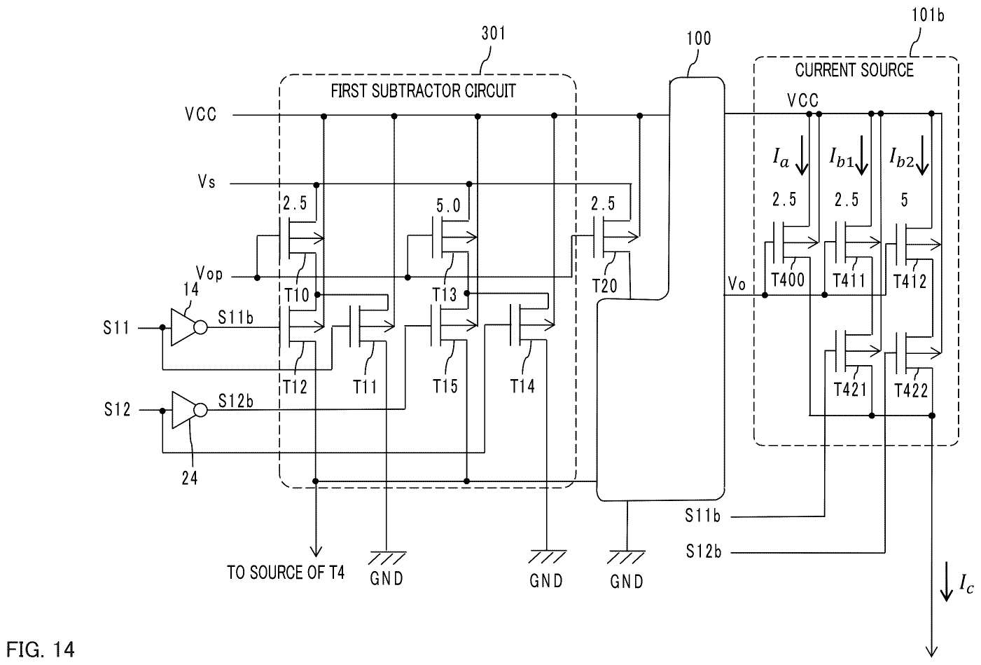

FIG. 14 is a diagram illustrating a part of the integrated circuit 1b of the fourth embodiment and a first subtractor circuit 301. The integrated circuit 1b includes the transistor T20, the bias voltage source 100, the current source 101b, the inverters 14, 24, and the first subtractor circuit 301. The bias voltage source 100 has the configuration as with the configuration illustrated in FIG. 12.

### (First Subtractor Circuit 301)

The first subtractor circuit 301 has the configuration and operation as with the subtractor circuit 22 illustrated in FIG. 5 and the like, and thus description thereof is omitted.

### (Bias Current Source 50b)

The bias current source 50b includes the bias voltage source 100 and the current source 101b, and passes the bias current IC corresponding to the current flowing through the transistor T20.

### (Current Source 101b)

The current source 101b passes the bias current IC corresponding to current I1, based on the bias voltage Vo corresponding to the current I5 passed by the transistor T20.

The current source 101b includes the transistors T400, transistors T411, T412, T421, T422. Note that the numerical value “2.5” given to the transistor T400 in FIG. 14 is a relative value when the current flowing through the transistor T3 is taken as 100. Further, the numerical values “2.5”, “5.0” given to the transistors T411, T412, respectively, are relative values when the current flowing through the transistor T400 is taken as 100.

### (Transistor T411)

The transistor T411 is a PMOS transistor in an embodiment of the present disclosure, and has a source electrode, a gate electrode, and a drain electrode.

The transistor T411 has the source electrode connected to the terminal TE1, and the gate electrode to receive the bias voltage Vo, and passes a current Ib1 having a current value corresponding to the value of the current flowing through the transistor T10. In an embodiment of the present disclosure, the current value of the current Ib1 is 1/40 times the current value of the current flowing through the transistor T10.

### (Transistor T412)

The transistor T412 is a PMOS transistor in an embodiment of the present disclosure, and has a source electrode, a gate electrode, and a drain electrode.

The transistor T412 has the source electrode connected to terminal TE1, and the gate electrode to receive the bias voltage Vo, and passes a current Ib2 corresponding to the value of the current flowing through the transistor T13. In an embodiment of the present disclosure, the current value of the current Ib2 is 1/40 times the value of the current flowing through the transistor T13.

### (Transistor T421)

The transistor T421 is a PMOS transistor in an embodiment of the present disclosure, and has a source electrode, a gate electrode, and a drain electrode.

The transistor T421 is provided between the transistor T411 and the overcurrent detection circuit 102, and the voltage corresponding to a signal S11b is applied to the gate electrode of the transistor T421. The drain electrode thereof is connected to the drain electrode of the transistor T400. Further, the transistor T421 is off when signal S11b is high, and is on when signal S11b is low. Note that the signal S11b is a signal outputted by the inverter 14.

### (Transistor T422)

The transistor T422 is a PMOS transistor in an embodiment of the present disclosure, and has a source electrode, a gate electrode, and a drain electrode.

The transistor T422 is provided between the transistor T412 and the overcurrent detection circuit 102, and the voltage corresponding to a signal S12b is applied to the gate electrode of the transistor T422. The drain electrode thereof is connected to the drain electrode of the transistor T400. Further, the transistor T422 is off when the signal S12b is high, and is on when the signal S12b is low. Note that the signal S12b is a signal outputted by the inverter 24.

Accordingly, when both of the signals S11b and S12b are high, the current source 101b passes the current Ia as the bias current Ic. In this case, the bias current Ic is the current having a current value corresponding to the value of the current flowing through the transistor T3. In other words, the current source 101b passes the bias current IC having a current value corresponding to the current value obtained by subtracting the currents flowing through the transistor T10 and the transistor T13 from the current I2.

Further, when the signal S11b is low and the signal S12b is high, the current source 101b passes, as the bias current Ic, the current obtained by adding the current Ib1 to the current Ia. In this case, the bias current Ic results in having a current value corresponding to the value of the current obtained by adding the current flowing through the transistor T3 and the current I4 flowing through the transistor T10. In other words, the current source 101b passes the bias current IC having a current value corresponding to the value of the current obtained by subtracting the current flowing through the transistor T13 from the current I2.

Further, when the signal S11b is high and the signal S12b is low, the current source 101b passes, as the bias current Ic, the current obtained by adding the current Ib2 to the current Ia. In this case, the bias current Ic results in having a current value corresponding to the value of the current obtained by adding the current flowing through the transistor T3 and the current flowing through the transistor T13. In other words, the current source 101b passes the bias current IC having a current value corresponding to the value of the current obtained by subtracting the current flowing through the transistor T10 from the current I2.

Further, when both of the signals S11b and S12b are low, the current source 101b passes, as the bias current Ic, the current obtained by adding the current Ib1 and the current Ib2 to the current Ia. In this case, the bias current Ic results in having a current value corresponding to the value of the current obtained by adding the current flowing through the transistor T3 and the currents flowing through the transistors T10 and T13. In other words, the current source 101b passes the bias current IC having a current value corresponding to the value of the current I2.

That is, the current source 101b changes the current value of the bias current IC in four stages, and passes the bias current IC having a current value corresponding to the value of the current flowing through the resistor R.

### Fifth Embodiment

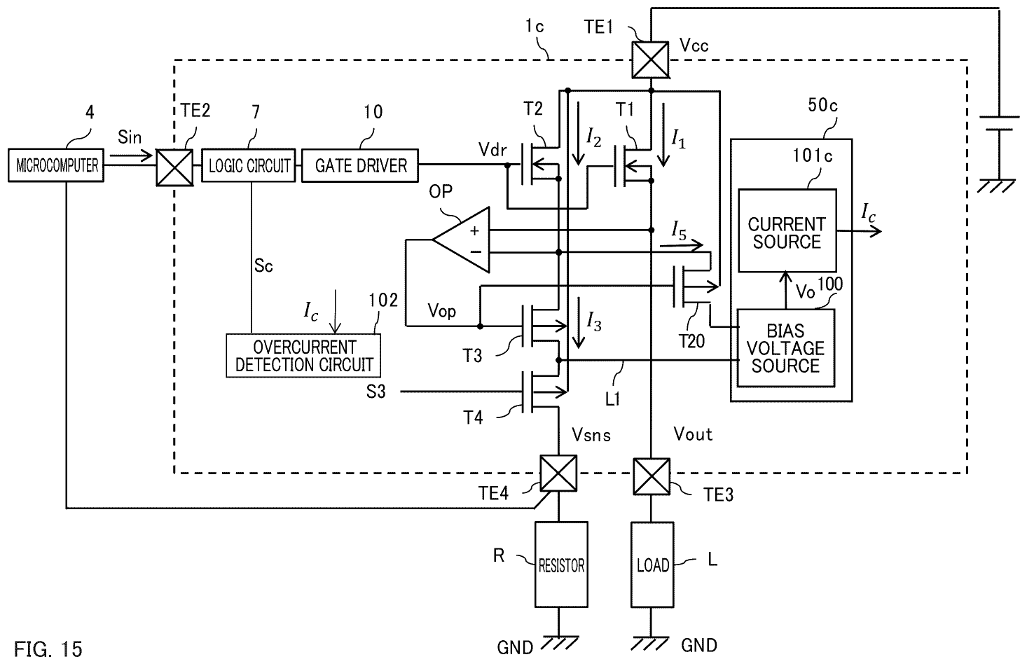

FIG. 15 is a diagram for describing an overview of an integrated circuit 1c of a fifth embodiment. The integrated circuit 1c is a circuit that drives the load L, in response to the drive signal Sin from the microcomputer 4. The integrated circuit 1c of the fifth embodiment includes the terminals TE1 to TE4, the logic circuit 7, the gate driver 10, the transistors T1 to T4, T20, the operational amplifier OP, a bias current source 50c, which includes the bias voltage source 100 and a current source 101c, and the overcurrent detection circuit 102. The configurations and operations of components other than the current source 101c are as with those of the third embodiment illustrated in FIG. 10, and thus description thereof is omitted.

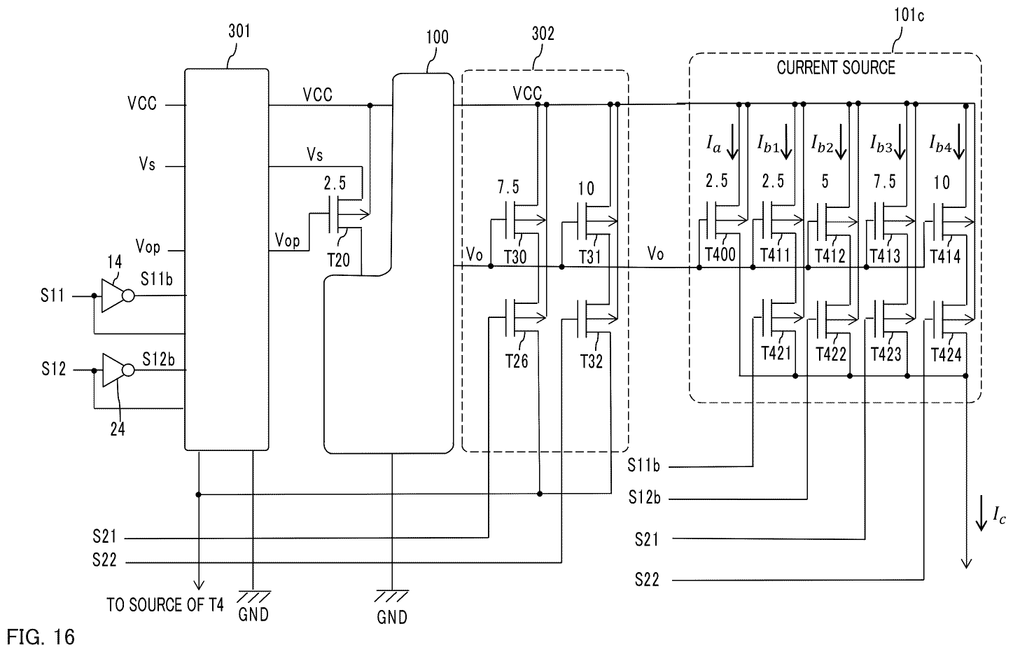

FIG. 16 is a diagram for describing a part of the integrated circuit 1c of the fifth embodiment. FIG. 16 is a diagram illustrating a part of the integrated circuit 1c and the first subtractor circuit 301 and a first adder circuit 302, and the integrated circuit 1c includes the transistor T20, the bias voltage source 100, the current source 101c, the inverters 14, 24, the first subtractor circuit 301, and the first adder circuit 302. The bias voltage source 100 has the configuration as with the configuration illustrated in FIG. 12. The first subtractor circuit 301 has the configuration as with the configuration illustrated in FIG. 14.

### (First Adder Circuit 302)

The first adder circuit 302 includes the transistor T26 and T30 to T32. Note that the configurations and operations of the transistors T26, T30 to T32 are as with those in the second embodiment, and thus description thereof is omitted.

### (Bias Current Source 50c)

The bias current source 50c includes the bias voltage source 100 and the current source 101c, and passes the bias current IC corresponding to the current flowing through the transistor T20.

### (Current Source 101c)

As illustrated in FIG. 16, the current source 101c passes the bias current IC corresponding to the current I1, based on the bias voltage Vo corresponding to the current I5 passed by the transistor T20. The current source 101c includes the transistors T400, T411, T412, T421, T422, transistors T413, T414, T423, T424. Note that the numerical value “2.5” given to the transistor T400 in FIG. 16 is a relative value when the current flowing through the transistor T3 is taken as 100. Further, the numerical values “2.5”, “5.0”, “7.5”, and “10” respectively given to the transistors T411, T412, T413, and T414 are relative values when the current flowing through the transistor T400 is taken as 100.

### (Transistor T413)

The transistor T413 is a PMOS transistor in an embodiment of the present disclosure, and has a source electrode, a gate electrode, and a drain electrode.

The transistor T413 has the source electrode connected to the terminal TE1, and the gate electrode to receive the bias voltage Vo, and passes a current Ib3 corresponding to the current flowing through the transistor T30. In an embodiment of the present disclosure, the current value of the current Ib3 is 1/40 times the value of the current flowing through the transistor T30.

### (Transistor T414)

The transistor T414 is a PMOS transistor in an embodiment of the present disclosure, and has a source electrode, a gate electrode, and a drain electrode.

The transistor T414 has the source electrode connected to the terminal TE1, and the gate electrode to receive the bias voltage Vo, and passes a current Ib4 corresponding to the current value according to the current flowing through the transistor T31. In an embodiment of the present disclosure, the current value of the current Ib4 is 1/40 times the value of the current flowing through the transistor T31.

### (Transistor T423)

The transistor T423 is a PMOS transistor in an embodiment of the present disclosure, and has a source electrode, a gate electrode, and a drain electrode.

The transistor T423 is provided between the transistor T413 and the overcurrent detection circuit 102, and the voltage corresponding to the signal S21 is applied to the gate electrode of the transistor T423. The drain electrode thereof is connected to the drain electrode of the transistor T400. Further, the transistor T423 is off when the signal S21 is high, and is on when the signal S21 is low.

### (Transistor T424)

The transistor T424 is a PMOS transistor in an embodiment of the present disclosure, and has a source electrode, a gate electrode, and a drain electrode.

The transistor T424 is provided between the transistor T414 and the overcurrent detection circuit 102, and the voltage corresponding to the signal S22 is applied to the gate electrode of the transistor T424. The drain electrode thereof is connected to the drain electrode of the transistor T400. Further, the transistor T424 is off when the signal S22 is high, and is on when the signal S22 is low.

Note that the current source 101c operates, in the same manner as the current source 101b, in response to the signals S11b, S12b, and further, passes the bias current IC in response to the signals S21, S22. Thus, in the following, it is assumed that the predetermined signals S11b, S12b are being inputted thereto and how the current source 101c changes the bias current Ic according to the levels of the signals S21, S22 will be described.

When both of the signals S21, S22 are high, the current source 101c passes the bias current Ic obtained by adding the current based on the signals S11b, S12b to the current Ia.

Further, when the signal S21 is low and the signal S22 is high, the current source 101c passes, as the bias current Ic, the current obtained by adding, to the current Ia, the current based on the signals S11b, S12b and the current Ib3. In this case, the current source 101c passes the bias current Ic having a current value obtained by adding, to the current Ia, the current based on signals S11b, S12b and the current having a current value corresponding to the value of the current flowing through the transistor T30.

Further, when the signal S21 is high and the signal S22 is low, the current source 101c passes, as the bias current Ic, the current obtained by adding, to the current Ia, the current based on the signals S11b, S12b and the current Ib4. In this case, the current source 101c passes the bias current Ic having a current value obtained by adding, to current Ia, the current based on signals S11b, S12b and the current having a current value corresponding to the value of the current flowing through the transistor T31.

Further, when both of the signals S21, S22 are low, the current source 101c passes, as the bias current Ic, the current obtained by adding, to the current Ia, the current based on the signals S11b, S12b and the currents Ib3, Ib4, In this case, the current source 101c passes the bias current Ic having a current value equal to the value of the current obtained by adding, to current Ia, the current based on the signals S11b, S12b and the current having a current value corresponding to the value of the current flowing through the transistors T30 and T31.

That is, in the same manner as described with reference to FIG. 5, the current source 101c changes the current value of the bias current IC in ten stages in response to the signals S11b, S12b, S21, and S22, and passes the bias current IC having a current value corresponding to the value of the current flowing through the resistor R.

### SUMMARY

The integrated circuit 1, 2, 3 in an embodiment described above includes: the transistor T1 having the drain electrode to receive the predetermined voltage, the gate electrode to receive the control voltage, and the source electrode, the transistor T1 being configured to pass the current I1 to the load; the transistor T2 having the drain electrode to receive the predetermined voltage, the gate electrode to receive the control voltage, and the source electrode, the transistor T2 being configured to pass the current I2 corresponding to the current I1; the transistor T3 connected between the source electrode of the transistor T2 and the predetermined line 1; the operational amplifier OP configured to control the transistor T3 such that the voltage at the source electrode of the transistor T1 and the voltage at the source electrode of the transistor T2 are equal; and the subtractor circuit 12, 22 configured to, when the first condition is satisfied, pass the current I4 to the ground, the current I4 being a part of the current I2.

According to such a configuration, it is possible to prevent the ratio between the drive current of the transistor T1 and the current of the transistor T2 from deviating from a desired value.

In the integrated circuit 1, 2, 3 described above, the subtractor circuit 12, 22 includes the transistor T10 having the source electrode connected to the source electrode of the transistor T2, the gate electrode to receive the output voltage of the operational amplifier OP, and the drain electrode, and the transistor T11 located between the drain electrode of the transistor T10 and the ground, the transistor T11 being configured to be turned on when the first condition is satisfied. According to such a configuration, it is possible to perform subtraction by turning on the transistor T11 only when subtraction is needed.

The integrated circuit 1 described above further includes the adder circuit 13 configured to add the current I6 to the current flowing through the predetermined line L1 via the transistor T3, when the second condition is satisfied. According to such a configuration, addition can be performed when the current I2 decreases below the ideal current due to manufacturing variations.

In the integrated circuit 1, 2, 3 described above, the subtractor circuit 12, 22 includes the transistor T12 located between the transistor T10 and the predetermined line L1. Such a configuration facilitates adjusting the absolute values of the amounts of correction in subtraction and addition to the same value.

In the integrated circuit 1, 2, 3 described above, the subtractor circuit 12, 22 includes the inverter 14 configured to turn on and off the transistors T11 and T12 complementarily. According to such a configuration, it is possible to, when subtraction is not performed, set the amount of correction by subtraction to zero, and, when subtraction is performed, set the amount of correction by subtraction to a desired amount.

In the integrated circuit 1, 2, 3 described above, the adder circuit 13, 23 includes the transistor T20 having the source electrode connected to the source electrode of the transistor T2, the gate electrode to receive the output voltage of the operational amplifier OP, and the drain electrode, the transistor T25 configured to generate the current corresponding to the current flowing through the transistor T20, and the transistor T26 located between the transistor T25 and the predetermined line L1, the transistor T26 being configured to be turned on when the second condition is satisfied. According to such a configuration, it is possible to perform addition by turning on the transistor T26 only when addition is needed.

In the integrated circuit described above, the current I4 may be different from the current I6. According to such a configuration, many more steps of subtraction or addition can be performed.

The integrated circuit 1, 2, 3 of an embodiment includes: the transistor T1 having the drain electrode to receive the predetermined voltage, the gate electrode to receive the control voltage, and the source electrode, the transistor T1 being configured to pass the current I1 to the load L; the transistor T2 having the drain electrode to receive the predetermined voltage, the gate electrode to receive the control voltage, and the source electrode, the transistor T2 being configured to pass the current I2 corresponding to current I1; the transistor T3 connected between the source electrode of the transistor T2 and the predetermined line 1, the operational amplifier OP configured to control the transistor T3 such that the voltage at the source electrode of the transistor T1 and the voltage at the source electrode of the transistor T2 are equal, and the adder circuit configured to add the current I6 to the current flowing through the predetermined line 1 via the transistor T3, when the second condition is satisfied.

According to such a configuration, it is possible to prevent the ratio between the drive current of the transistor T1 and the current of the transistor T2 from deviating from the desired value.

In the integrated circuit 1a, 1b, 1c of an embodiment includes: the transistor T1 having the drain electrode to receive the predetermined voltage, the gate electrode to receive the control voltage, and the source electrode, the transistor T1 being configured to pass the current I1 through the load L; the transistor T2 having the drain electrode to receive the predetermined voltage, the gate electrode to receive the control voltage, and the source electrode, the transistor T2 being configured to pass the current I2 corresponding to the current I1; the transistor T3 connected between the source electrode of the transistor T2 and the predetermined line 1; the operational amplifier OP configured to control the transistor T3, T20 such that the voltage at the source electrode of the transistor T1 and the voltage at the source electrode of the transistor T2 are equal; the transistor T20 connected to the source electrode of the transistor T2, the transistor T20 being configured to be controlled by the operational amplifier OP together with the transistor T3; the bias current source configured to pass the bias current corresponding to the current flowing through the transistor T20; and the overcurrent detection circuit 102 configured to detect whether the current I1 is overcurrent, based on the current of the bias current source.

According to such a configuration, the current value to detect whether the current I1 overcurrent can be made constant.

In the integrated circuit 1b, 1c described above further includes the first subtractor circuit 301 configured to, when the first condition is satisfied, pass the current I4 to the ground, according to the current flowing through the transistor T3, the current I4 being a part of the current I2, wherein the bias current source reduces the current value of the bias current IC, when the first condition is satisfied.

According to such a configuration, even if the ratio of the drive current of the transistor T1 to the current of the transistor T2 (I1/I2) decreases, it is possible to detect whether the current I1 is overcurrent, based on the bias current Ic corresponding to the current I1, thereby improving detection accuracy.

In the integrated circuit 1c described above further includes the first adder circuit 302 configured to, when the second condition is satisfied, add the current corresponding to the current flowing through the transistor T20 to the current I2, wherein the bias current source increases the bias current IC when the second condition is satisfied.

According to such a configuration, even if the ratio of the drive current of the transistor T1 to the current of the transistor T2 (I1/I2) increases, it is possible to detect whether the current I1 is overcurrent, based on the bias current Ic corresponding to the current I1, thereby improving detection accuracy.

The integrated circuit 1a described above includes the first adder circuit 300 configured to add the current corresponding to the current flowing through the transistor T20 to the current I2 when the second condition is satisfied, wherein the bias current source increases the bias current IC when the second condition is satisfied.

According to such a configuration, even if the ratio of the drive current of the transistor T1 to the current of the transistor T2 (I1/I2) increases, it is possible to detect whether the current I1 is overcurrent, based on the bias current Ic corresponding to the current I1, thereby improving detection accuracy.

In the integrated circuit 1a, 1b, 1c described above, the overcurrent detection circuit 102 includes the resistor R1 provided between the bias current source and the ground, the resistor R1 allowing the bias current IC to flow therethrough, the reference voltage output circuit 200 configured to output the reference voltage to detect whether the current I1 is overcurrent, and the comparator circuit 201 configured to compare the voltage generated at the resistor R1 with the reference voltage, to thereby detect whether the current I1 is overcurrent.

According to such a configuration, by using the bias current IC to detect whether the current I1 is overcurrent, the transistor T1 is no longer affected by the positive temperature characteristics of the on-resistance of the transistor T1, and thus the current value to detect whether the current I1 flowing through the transistor T1 is overcurrent results in being constant.

The present disclosure is directed to provision of an integrated circuit capable of suppressing deviation of the ratio between the drive current of a main transistor and the current of a sense transistor from a desired value.

According to the present disclosure, it is possible to provide an integrated circuit capable of suppressing deviation of the ratio between the drive current of a main transistor and the current of a sense transistor from a desired value.

What is claimed is:

1. An integrated circuit, comprising:
a first transistor having
an electrode on a high potential side thereof to receive a predetermined voltage,
a control electrode to receive a control voltage, and
an electrode on a low potential side thereof, the first transistor being configured to send a first current to a load connected to the integrated circuit;
a second transistor having
an electrode on a high potential side thereof to receive the predetermined voltage,
a control electrode to receive the control voltage, and
an electrode on a low potential side thereof, the second transistor being configured to send a second current corresponding to the first current;
a third transistor connected between the electrode on the low potential side of the second transistor and a predetermined line;
an operational amplifier configured to control the third transistor such that a voltage at the electrode on the low potential side of the first transistor and a voltage at the electrode on the low potential side of the second transistor are equal; and
a subtractor circuit configured to, in response to a first condition being satisfied, send a third current to a ground, the third current being a part of the second current.

2. The integrated circuit according to claim 1, wherein the subtractor circuit includes
a fourth transistor having
an electrode on a high potential side thereof, the electrode being connected to the electrode on the low potential side of the second transistor,
a control electrode to receive an output voltage of the operational amplifier, and
an electrode on a low potential side thereof; and
a first switch located between the electrode on the low potential side of the fourth transistor and the ground, the first switch being configured to be turned on when the first condition is satisfied.

3. The integrated circuit according to claim 2, wherein the subtractor circuit further includes a second switch located between the fourth transistor and the predetermined line.

4. The integrated circuit according to claim 3, wherein the subtractor circuit further includes a switch control circuit configured to turn on and off the first switch and the second switch, complementarily.

5. The integrated circuit according to claim 1, further comprising:
an adder circuit configured to add a fourth current to the second current, in response to a second condition being satisfied.

6. The integrated circuit according to claim 5, wherein the adder circuit includes
a fifth transistor having
an electrode on a high potential side thereof, the electrode being connected to the electrode on the low potential side of the second the transistor,
a control electrode to receive an output voltage of the operational amplifier, and
an electrode on a low potential side thereof,
a sixth transistor configured to generate a current corresponding to a current flowing through the fifth transistor, and
a third switch located between the sixth transistor and the predetermined line, the third switch being configured to be turned on in response to the second condition being satisfied.

7. The integrated circuit according to claim 5, wherein the third current is different from the fourth current.

8. The integrated circuit according to claim 2, further comprising:
an adder circuit configured to add a fourth current to the second current, in response to a second condition being satisfied.

9. The integrated circuit according to claim 8, wherein the adder circuit includes
a fifth transistor having
an electrode on a high potential side thereof, the electrode being connected to the electrode on the low potential side of the second transistor,
a control electrode to receive an output voltage of the operational amplifier, and
an electrode on a low potential side thereof;
a sixth transistor configured to generate a current corresponding to a current flowing through the fifth transistor, and
a third switch located between the sixth transistor and the predetermined line, the third switch being configured to be turned on in response to the second condition being satisfied.

10. The integrated circuit according to claim 9, wherein the third current is different from the fourth current.

11. An integrated circuit, comprising:
a first transistor having
an electrode on a high potential side thereof to receive a predetermined voltage, and
a control electrode to receive a control voltage, and
an electrode on a low potential side thereof, the first transistor being configured to send a first current to a load connected to the integrated circuit;
a second transistor having
an electrode on a high potential side thereof to receive the predetermined voltage,
a control electrode to receive the control voltage, and
an electrode on a low potential side thereof, the second transistor being configured to send a second current corresponding to the first current;
a third transistor connected between the electrode on the low potential side of the second transistor and a predetermined line;
an operational amplifier configured to control the third transistor such that a voltage at the electrode on the low potential side of the first transistor and a voltage at the electrode on the low potential side of the second transistor are equal; and
an adder circuit configured to add a fourth current to the second current, in response to a predetermined condition being satisfied.

12. The integrated circuit according to claim 11, wherein the adder circuit includes
a fifth transistor having
an electrode on a high potential side thereof, the electrode being connected to the electrode on the low potential side of the second transistor,
a control electrode to receive an output voltage of the operational amplifier, and
an electrode on a low potential side thereof,
a sixth transistor configured to generate a current corresponding to a current flowing through the fifth transistor, and
a third switch located between the sixth transistor and the predetermined line, the third switch being configured to be turned on, in response to the predetermined condition being satisfied.

13. An integrated circuit, comprising:
a first transistor having
an electrode on a high potential side thereof to receive a predetermined voltage, and
a control electrode to receive a control voltage, and
an electrode on a low potential side thereof, the first transistor being configured to send a first current to a load connected to the integrated circuit;
a second transistor having
an electrode on a high potential side thereof to receive the predetermined voltage, and
a control electrode to receive the control voltage, and
an electrode on a low potential side thereof, the second transistor being configured to send a second current corresponding to the first current;
a third transistor connected between the electrode on the low potential side of the second transistor and a predetermined line;
an operational amplifier configured to control the third transistor such that a voltage at the electrode on the low potential side of the first transistor and a voltage at the electrode on the low potential side of the second transistor are equal; and
another transistor connected to the electrode on the low potential side of the second transistor, said another transistor being configured to be controlled by the operational amplifier together with the third transistor;
a bias current source configured to generate a bias current corresponding to a current flowing through said another transistor; and
an overcurrent detection circuit configured to detect whether the first current is an overcurrent, based on the bias current.

14. The integrated circuit according to claim 13, further comprising:
a first subtractor circuit configured to, in response to a first condition being satisfied, send a third current to a ground, according to a current flowing through the third transistor, the third current being a part of the second current, wherein
the bias current source reduces a current value of the bias current, in response to the first condition being satisfied.

15. The integrated circuit according to claim 14, further comprising:
a first adder circuit configured to add a fourth current corresponding to a current flowing through said another transistor to the second current, in response to a predetermined condition being satisfied, wherein
the bias current source increases the bias current, in response to the predetermined condition being satisfied.

16. The integrated circuit according to claim 13, further comprising:
a first adder circuit configured to add, to the second current, a fourth current corresponding to a current flowing through said another transistor, in response to a predetermined condition being satisfied, wherein
the bias current source increases the bias current, in response to the predetermined condition being satisfied.

17. The integrated circuit according to claim 13, wherein the overcurrent detection circuit includes:
a resistor provided between the bias current source and a ground, for allowing the bias current to flow therethrough,
a reference voltage output circuit configured to output a reference voltage to detect whether the first current is an overcurrent, and
a comparator circuit configured to compare a voltage generated at the resistor with the reference voltage, to thereby detect whether the first current is an overcurrent.
